(19) United States
(12) Patent Application Publication
(10) Pub. No.: US 2022/0302152 A1
(43) Pub. Date: Sep. 22, 2022

(54) SEMICONDUCTOR DEVICE AND METHOD OF MANUFACTURING THE SAME

(71) Applicant: Kioxia Corporation, Tokyo (JP)

(72) Inventors: Koichi SAKATA, Yokkaichi (JP); Junichi SHIBATA, Yokkaichi (JP)

(73) Assignee: Kioxia Corporation, Tokyo (JP)

(21) Appl. No.: 17/475,014

(22) Filed: Sep. 14, 2021

(30) Foreign Application Priority Data
Mar. 16, 2021 (JP) 2021-042761

(51) Int. Cl. H01L 27/11556; H01L 27/11519; H01L 23/522; H01L 23/528

(52) U.S. Cl. CPC H01L 27/11556; H01L 27/11519; H01L 23/5226; H01L 23/5283

(57) ABSTRACT

In one embodiment, a semiconductor device includes first electrode layers spaced from one another in a first direction, and second electrode layers provided above the first electrode layers, and spaced from one another in the first direction. The device further includes a first columnar portion extending in the first direction in the first electrode layers, and including a first semiconductor layer, and a second columnar portion provided on the first columnar portion, extending in the first direction in the second electrode layers, and including a second semiconductor layer. The first columnar portion includes a first portion having a first width, and a second portion having a second width larger than the first width above the first portion. The second columnar portion includes a third portion having a third width, and a fourth portion having a fourth width larger than the third width above the third portion.

### CROSS REFERENCE TO RELATED APPLICATION

This application is based upon and claims the benefit of priority from the prior Japanese Patent Application No. 2021-042761, filed on Mar. 16, 2021, the entire contents of which are incorporated herein by reference.

### FIELD

Embodiments described herein relate to a semiconductor device and a method of manufacturing the same.

### BACKGROUND

In a three-dimensional semiconductor memory, there arises a problem that an insulator for dividing an electrode layer contacts a columnar portion that includes a charge storage layer and a channel semiconductor layer.

### BRIEF DESCRIPTION OF THE DRAWINGS

FIG. 1 is a cross-sectional view illustrating a structure of a semiconductor device of a first embodiment;

FIG. 2 is an enlarged sectional view illustrating the structure of the semiconductor device of the first embodiment;

FIG. 3 is another cross-sectional view illustrating the structure of the semiconductor device of the first embodiment;

FIG. 4 is a cross-sectional view illustrating a structure of a semiconductor device in a comparative example of the first embodiment;

FIG. 5 is another cross-sectional view illustrating the structure of the semiconductor device in the comparative example of the first embodiment;

FIGS. 6A to 14 are cross-sectional views illustrating a method of manufacturing the semiconductor device of the first embodiment;

FIG. 15 is a cross-sectional view illustrating a structure of a semiconductor device of a second embodiment;

FIG. 16 is a cross-sectional view illustrating a structure of a semiconductor device of a first modification to the second embodiment;

FIG. 17 is a cross-sectional view illustrating a structure of a semiconductor device according a second modification to the second embodiment;

FIG. 18 is a cross-sectional view illustrating a structure of a semiconductor device of a third embodiment;

FIG. 19 is a cross-sectional view illustrating a structure of a semiconductor device of a fourth embodiment; and

FIGS. 20A to 25 are cross-sectional views illustrating a method of manufacturing the semiconductor device of the fourth embodiment.

### DETAILED DESCRIPTION

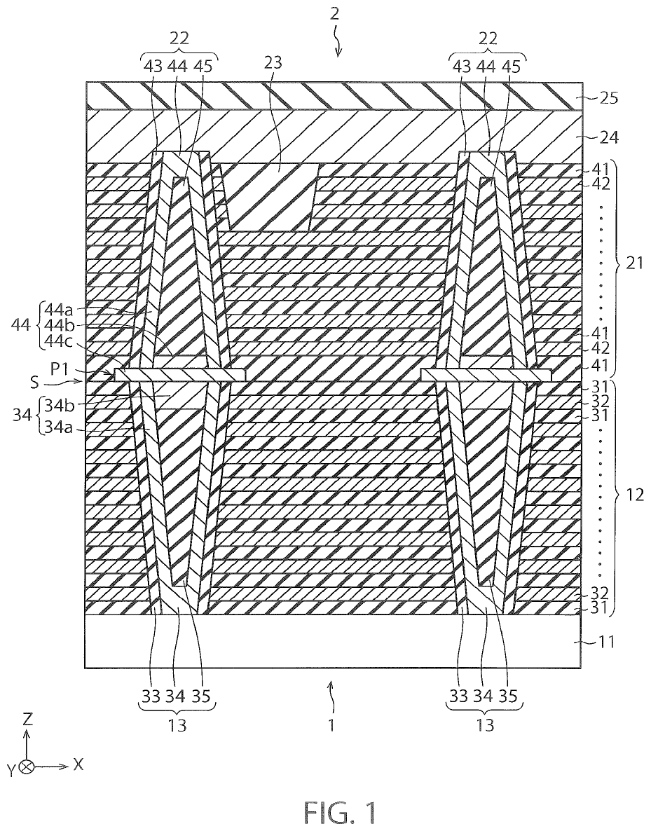

Embodiments will now be explained with reference to the accompanying drawings. In FIGS. 1 to 25, the same components are respectively assigned the same reference numerals, and hence overlapping description is omitted.

In one embodiment, a semiconductor device includes a plurality of first electrode layers spaced from one another in a first direction, and a plurality of second electrode layers provided above the first electrode layers, and spaced from one another in the first direction. The device further includes a first columnar portion extending in the first direction in the plurality of first electrode layers, and including a first semiconductor layer, and a second columnar portion provided on the first columnar portion, extending in the first direction in the plurality of second electrode layers, and including a second semiconductor layer. The device further includes a first charge storage layer provided between the plurality of first electrode layers and the first semiconductor layer, and a second charge storage layer provided between the plurality of second electrode layers and the second semiconductor layer. The second semiconductor layer is directly provided on the first semiconductor layer, or is provided on the first semiconductor layer via another semiconductor layer. The first columnar portion includes a first portion having a first width in a second direction intersecting the first direction, and a second portion provided above the first portion and having a second width larger than the first width in the second direction. The second columnar portion includes a third portion having a third width in the second direction, and a fourth portion provided above the third portion and having a fourth width larger than the third width in the second direction.

### First Embodiment

FIG. 1 is a cross-sectional view illustrating a structure of a semiconductor device of a first embodiment. The semiconductor device in FIG. 1 is a three-dimensional semiconductor memory, for example.

The semiconductor device in FIG. 1 is manufactured by bonding a memory substrate 1 and a memory substrate 2 to each other. FIG. 1 illustrates a bonding face S between the memory substrate 1 and the memory substrate 2.

FIG. 1 further illustrates an X-direction, a Y-direction, and a Z-direction perpendicular to one another. In the specification, a +Z-direction is treated as an upward direction, and a −Z-direction is treated as a downward direction. In FIG. 1, the memory substrate 2 is arranged on the memory substrate 1. The −Z-direction may match a direction of gravity, or may not match the direction of gravity. The X-direction, the Y-direction, and the Z-direction intersect one another. The Z-direction is an example of first and fourth directions. The X-direction is an example of a second direction. The Y-direction is an example of a third direction.

The memory substrate 1 includes a substrate 11, a stacked film 12, and a plurality of columnar portions 13. The columnar portions 13 are each an example of a first columnar portion. The memory substrate 2 includes a stacked film 21, a plurality of columnar portions 22, an embedded insulator 23, an interconnection layer 24, and a passivation insulator 25. The columnar portions 22 are each an example of a second columnar portion. The embedded insulator 23 is an example of a third insulator.

The stacked film 12 includes a plurality of insulators 31 and a plurality of electrode layers 32. Each of the columnar portions 13 includes a memory insulator 33, a channel semiconductor layer 34, and a core insulator 35. The channel semiconductor layer 34 includes a semiconductor layer 34a and a semiconductor layer 34b. The electrode layer 32 is an example of a first electrode layer. The semiconductor layer 34a is an example of a first semiconductor layer. A charge storage layer (described below) in the memory insulator 33 is an example of a first charge storage layer.

The stacked film 21 includes a plurality of insulators 41 and a plurality of electrode layers 42. Each of the columnar portions 22 includes a memory insulator 43, a channel semiconductor layer 44, and a core insulator 45. The channel semiconductor layer 44 includes a semiconductor layer 44a, a semiconductor layer 44b, and a semiconductor layer 44c. The electrode layer 42 is an example of a second electrode layer. The semiconductor layer 44a is an example of a second semiconductor layer. A charge storage layer (described below) in the memory insulator 43 is an example of a second charge storage layer.

Further details of the semiconductor device in FIG. 1 will be described below.

The substrate 11 is a semiconductor substrate such as a silicon substrate. In FIG. 1, the Z-direction is parallel to a surface of the substrate 11, and the X-direction and the Y-direction are perpendicular to the surface of the substrate 11. In FIG. 1, the substrate 11 is upwardly arranged.

The stacked film 12 includes the plurality of insulators 31 and the plurality of electrode layers 32 alternately provided on the substrate 11. The electrode layers 32 are spaced from one another in the Z-direction above the substrate 11. The electrode layers 32 each function as a word line or a selection line. Each of the insulators 31 is an SiO₂ film (silicon oxide film), for example. Each of the electrode layers 32 is a metal layer including a TiN film (titanium nitride film) as a barrier metal layer and including a W (tungsten) layer as an electrode material layer, for example.

The columnar portions 13 are formed on the substrate 11 in the stacked film 12, and each have a columnar shape extending in the Z-direction. Each of the columnar portions 13 includes the memory insulator 33, the channel semiconductor layer 34, and the core insulator 35 formed in this order in the stacked film 12. The columnar portions 13 in the present embodiment each have a shape close to a circular columnar shape, and a planar shape of the columnar portion 13 is a circular shape. Note that a side face of each of the columnar portions 13 in the present embodiment is inclined with respect to the Z-direction, and a diameter in the vicinity of an upper end of the columnar portion 13 is larger than a diameter in the vicinity of a lower end of the columnar portion 13. Therefore, each of the columnar portions 13 in the present embodiment has a diameter that increases in the Z-direction. That is, a diameter of each of the columnar portions 13 at a height increases as the height increases. In FIG. 1, a width in the X-direction of each of the columnar portions 13 at a height increases as the height increases.

From another viewpoint, when two portions respectively having different heights in each of the columnar portions 13 are paid attention to, a width in the X-direction of the higher portion is larger than a width in the X-direction of the lower portion. The lower portion and the width thereof are an example of a first portion and a first width. The higher portion and the width thereof are an example of a second portion and a second width.

The memory insulator 33 is formed on respective side faces of the insulators 31 and the electrode layers 32 in the stacked film 12. The memory insulator 33 includes an SiO₂ film as a block insulator, includes an SiN film (silicon nitride film) as a charge storage layer, and includes an SiO₂ film or an SiON film (silicon oxynitride film) as a tunnel insulator, for example. The charge storage layer may be a semiconductor layer such as a polysilicon layer.

The semiconductor layer 34a in the channel semiconductor layer 34 is formed on a side face of the memory insulator 33 and an upper face of the substrate 11. The core insulator 35 is formed on a side face and an upper face of the semiconductor layer 34a. The semiconductor layer 34b in the channel semiconductor layer 34 is formed on the side face of the semiconductor layer 34a and an upper face of the core insulator 35, and contacts the semiconductor layer 34a. The semiconductor layers 34a and 34b are each an Si (silicon) layer such as a polysilicon layer. The core insulator 35 is an SiO₂ film, for example.

The stacked film 21 includes the plurality of insulators 41 and the plurality of electrode layers 42 alternately provided on the stacked film 12. The electrode layers 42 are spaced from one another in the Z-direction above the plurality of electrode layers 32. The electrode layers 42 each function as a word line or a selection line. Each of the insulators 41 is an SiO₂ film, for example. Each of the electrode layers 42 is a metal layer including a TiN film as a barrier metal layer and including a W layer as an electrode material layer, for example.

The columnar portions 22 are respectively formed on the columnar portions 13 in the stacked film 21, and each have a columnar shape extending in the Z-direction. Specifically, each of the columnar portions 22 is formed on the corresponding columnar portion 13, and is electrically connected to the corresponding columnar portion 13. Each of the columnar portions 22 includes the memory insulator 43, the channel semiconductor layer 44, and the core insulator 45 formed in this order in the stacked film 21. The columnar portions 22 in the present embodiment each have a shape close to a circular columnar shape, and a planar shape of the columnar portion 22 is a circular shape. Note that a side face of each of the columnar portions 22 in the present embodiment is inclined with respect to the Z-direction, and a diameter in the vicinity of an upper end of the columnar portion 22 is smaller than a diameter in the vicinity of a lower end of the columnar portion 22. Therefore, each of the columnar portions 22 in the present embodiment has a diameter that decreases in the Z-direction. That is, a diameter of each of the columnar portions 22 at a height decreases as the height increases. In FIG. 1, a width in the X-direction of each of the columnar portions 22 at a height decreases as the height increases.

From another viewpoint, when two portions respectively having different heights in each of the columnar portions 22 are paid attention to, a width in the X-direction of the higher portion is smaller than a width in the X-direction of the lower portion. The lower portion and the width thereof are an example of a third portion and a third width. The higher portion and the width thereof are an example of a fourth portion and a fourth width.

The memory insulator 43 is formed on respective side faces of the insulators 41 and the electrode layers 42 in the stacked film 21. The memory insulator 43 includes an SiO₂ film as a block insulator, includes an SiN film as a charge storage layer, and includes an SiO₂ film or an SiON film as a tunnel insulator, for example. The charge storage layer may be a semiconductor layer such as a polysilicon layer.

The semiconductor layer 44a in the channel semiconductor layer 44 is formed on a side face of the memory insulator 43 and a lower face of the interconnection layer 24. The core insulator 45 is formed on a side face and a lower face of the semiconductor layer 44a. The semiconductor layer 44b in the channel semiconductor layer 44 is formed on the side face of the semiconductor layer 44a and a lower face of the core insulator 45, and contacts the semiconductor layer 44a. The semiconductor layer 44c in the channel semiconductor layer 44 is formed on respective lower faces of the semiconductor layers 44a and 44b and respective upper faces of the semiconductor layers 34a and 34b, and contacts the semiconductor layers 44a, 44b, 34a, and 34b. Therefore, the channel semiconductor layer contacts the channel semiconductor layer 34, and is electrically connected to the channel semiconductor layer 34. The semiconductor layer 44c is a joint portion P1 that couples the channel semiconductor layer 34 and the channel semiconductor layer 44 to each other. The semiconductor layers 44a, 44b, and 44c are each an Si layer such as a polysilicon layer. The core insulator 45 is an SiO₂ film, for example.

The embedded insulator 23 is formed in only the stacked film 21 out of the stacked films 12 and 21, and extends in the Y-direction and the Z-direction. The semiconductor device of the present embodiment includes a plurality of embedded insulators 23. FIG. 1 illustrates one of the embedded insulators 23. The embedded insulator 23 is an SiO₂ film, for example. The embedded insulator 23 is formed in the insulators 41 and the electrode layers 42 in the stacked film 21. Each of the embedded insulators 23 in the present embodiment is arranged to contact none of the columnar portions 22 in the stacked film 21. Accordingly, the embedded insulator 23 in the present embodiment does not contact the memory insulator 43, the channel semiconductor layer 44, and the core insulator 45 in each of the columnar portions 22.

The interconnection layer 24 is formed on the stacked film 21, the columnar portions 22, and the embedded insulators 23, and is electrically connected to the channel semiconductor layer 44 in each of the columnar portions 22. The interconnection layer 24 may include only one of a semiconductor layer and a metal layer, or may include both the semiconductor layer and the metal layer. The interconnection layer 24 includes a polysilicon layer as the semiconductor layer, and includes a W layer, an Al (aluminum) layer, and a Cu (copper) layer as the metal layer.

The passivation insulator 25 is formed on the interconnection layer 24. The passivation insulator 25 is a stacked film including an SiO₂ film and other insulators, for example.

An upper face of the channel semiconductor layer 34 in each of the columnar portion 13 may have a solid shape such as a circular shape, or may have a hollow shape such as an annular shape. The upper face of the channel semiconductor layer 34 in the present embodiment has a solid shape because it is formed of the semiconductor layers 34a and 34b. Similarly, a lower face of the channel semiconductor layer 44 in each of the columnar portions 22 may have a solid shape, or may have a hollow shape. The lower face of the channel semiconductor layer 44 in the present embodiment has a solid shape because it is formed of the semiconductor layer 44c.

The upper face of the semiconductor layer 34a in the present embodiment has a hollow shape, and the lower face of the semiconductor layer 44a in the present embodiment has a hollow shape. Each of the columnar portions 13 includes the semiconductor layer 34b in the upper face of the semiconductor layer 34a, and each of the columnar portions 22 includes the semiconductor layer 44b in the lower face of the semiconductor layer 44a. The semiconductor layers 44a and 44b in the present embodiment are respectively formed on the semiconductor layers 34a and 34b via the semiconductor layer 44c.

The channel semiconductor layer 44 in the present embodiment includes the semiconductor layer 44c as the joint portion P1. Accordingly, the diameter of the lower face of the channel semiconductor layer 44 (the semiconductor layer 44c) is larger than the diameter of the upper face of the corresponding channel semiconductor layer 34, and is further larger than the diameter of an upper face of the corresponding columnar portion 13. This makes it possible to electrically connect the channel semiconductor layer 34 and the channel semiconductor layer 44 to each other in a preferred manner even if a position shift occurs between the columnar portion 13 and the columnar portion 22. The channel semiconductor layer 44 may not include the joint portion P1.

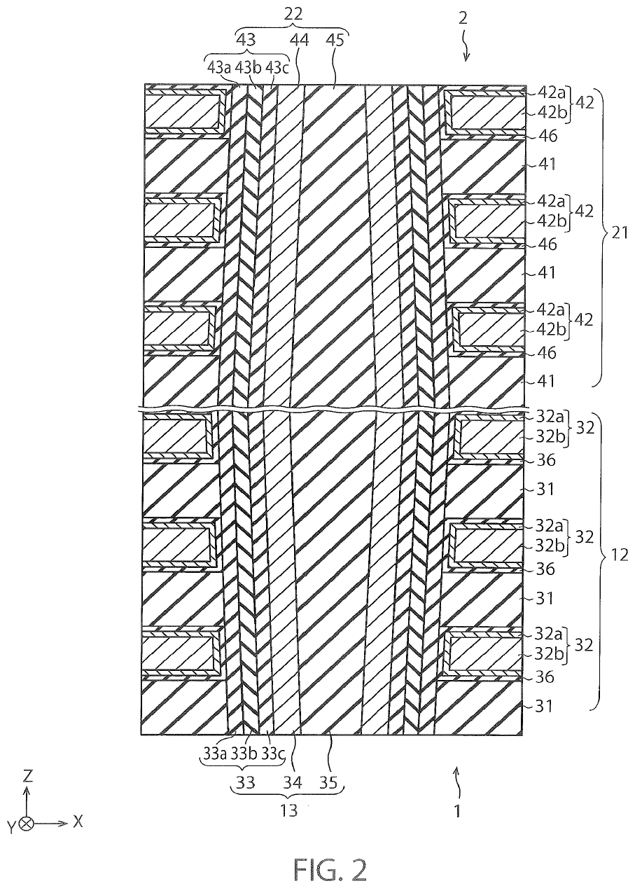

FIG. 2 is an enlarged sectional view illustrating the structure of the semiconductor device of the first embodiment.

FIG. 2 illustrates the columnar portion 13 that penetrates through the stacked film 12 and the columnar portion 22 that penetrates through the stacked film 21. The memory insulator 33 in the columnar portion 13 includes a block insulator 33a, a charge storage layer 33b, and a tunnel insulator 33c formed in this order on a side face of the stacked film 12. The memory insulator 43 in the columnar portion 22 includes a block insulator 43a, a charge storage layer 43b, a tunnel insulator 43c formed in this order on a side face of the stacked film 21. The block insulators 33a and 43a are each an SiO₂ film, for example. The charge storage layers 33b and 43b are each an SiN film, for example. The tunnel insulators 33c and 43c are each an SiO₂ film or an SiON film, for example. The charge storage layers 33b and 43b are respectively examples of first and second charge storage layers.

Each of the electrode layers 32 includes a barrier metal layer 32a and an electrode material layer 32b. The barrier metal layer 32a is a TiN film, for example. The electrode material layer 32b is a W layer, for example. Each of the electrode layers 32 is formed on an upper face of the insulator 31, a lower face of the insulator 31, and a side face of the block insulator 33a via a block insulator 36. The block insulator 36 is an aluminum oxide film, for example.

Each of the electrode layers 42 includes a barrier metal layer 42a and an electrode material layer 42b. The barrier metal layer 42a is a TiN film, for example. The electrode material layer 42b is a W layer, for example. Each of the electrode layers 42 is formed on a lower face of the insulator 41, an upper face of the insulator 41, and a side face of the block insulator 43a via a block insulator 46. The block insulator 46 is an aluminum oxide film, for example.

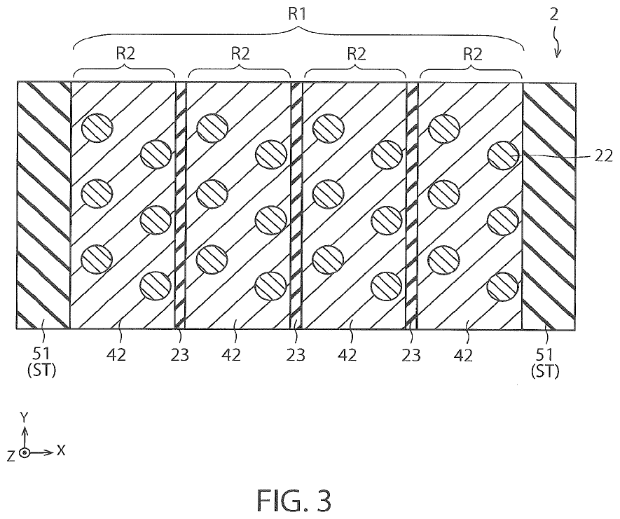

FIG. 3 is another cross-sectional view illustrating a structure of the semiconductor device of the first embodiment.

FIG. 3 illustrates an XY cross section that passes through the columnar portions 22 and the embedded insulator 23 illustrated in FIG. 1. The semiconductor device of the present embodiment includes the plurality of columnar portions 22, a plurality of embedded insulators 23, and a plurality of embedded insulators 51 in the memory substrate 2, as illustrated in FIG. 3. The embedded insulators 51 are respectively examples of first and second insulators, and each of the embedded insulators 23 is an example of a third insulator.

The semiconductor device of the present embodiment further includes one region R1 and a plurality of regions R2, as illustrated in FIG. 3. The region R1 corresponds to one finger of a three-dimensional semiconductor memory, for example. On the other hand, each of the regions R2 corresponds to one page of the three-dimensional semiconductor memory, for example. In FIG. 3, the one region R1 includes the four regions R2.

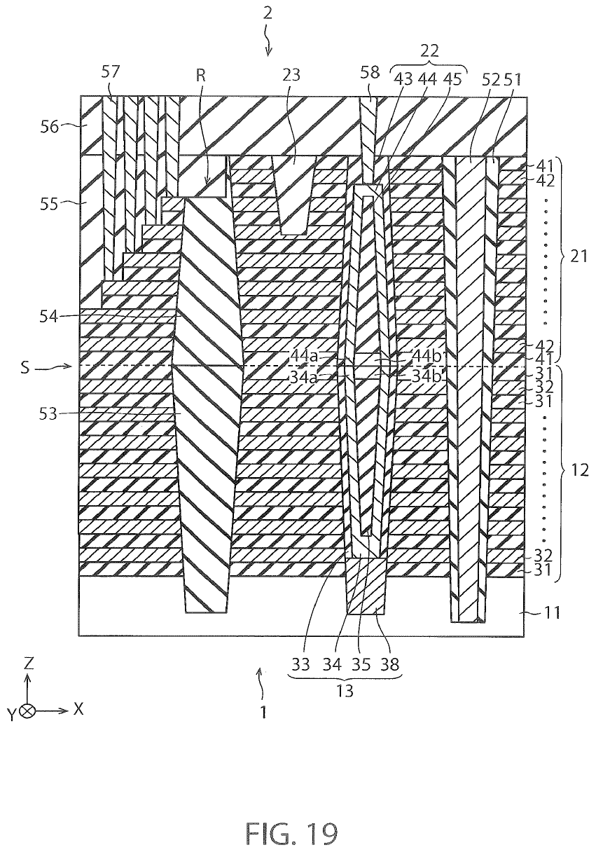

Each of the embedded insulators 51 is formed in the stacked films 12 and 21, and extends in the Y-direction and the Z-direction. FIG. 3 illustrates the two embedded insulators 51 adjacent to each other in the X-direction. The embedded insulators 51 are each an SiO₂ film, for example. Each of the embedded insulators 51 is formed in the insulators 31 and the electrode layers 32 in the stacked film 12 and in the insulators 41 and the electrode layers 42 in the stacked film 21. Each of the embedded insulators 51 is embedded in a slit ST formed in the stacked films 12 and 21. The semiconductor device of the present embodiment may include the embedded insulator 51 and an interconnection layer in this order in each of the slits ST. The embedded insulator 51 is illustrated in FIG. 19, described below.

Each of the embedded insulators 23 is formed in only the stacked film 21 out of the stacked films 12 and 21, and extends in the Y-direction and the Z-direction, as described above. FIG. 3 illustrates the three embedded insulators 23 positioned between the embedded insulators 51 and adjacent to one another in the X-direction. Each of the embedded insulators 23 in the present embodiment is arranged to contact none of the columnar portions 22 in the stacked film 21, as described above.

The region R1 corresponds to the finger of the three-dimensional semiconductor memory. FIG. 3 illustrates the one region R1 corresponding to the one finger. The embedded insulators 51 in the present embodiment respectively define boundaries in ±X-directions of the finger.

Each of the regions R2 corresponds to the page of the three-dimensional semiconductor memory. FIG. 3 illustrates the four regions R2 respectively corresponding to four pages. The embedded insulators 23 in the present embodiment define boundaries in the ±X-directions among the pages, and divide one finger into a plurality of pages.

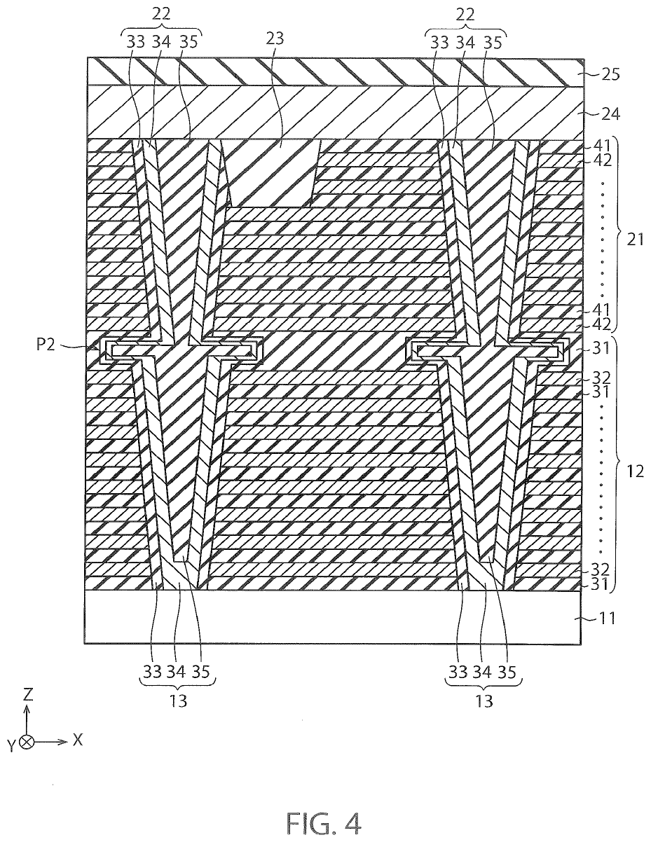

FIG. 4 is a cross-sectional view illustrating a structure of a semiconductor device in a comparative example of the first embodiment.

The semiconductor device (FIG. 1) of the first embodiment is manufactured by bonding the memory substrate 1 and the memory substrate 2 to each other. Therefore, each of the columnar portions 13 in the present embodiment has a diameter that increases in the Z-direction, and each of the columnar portions 22 in the present embodiment has a diameter that decreases in the Z-direction.

On the other hand, the semiconductor device (FIG. 4) in the comparative example is manufactured by forming stacked films 12 and 21 on a substrate 11 and forming columnar portions 13 and 22 and embedded insulators 23 in the stacked films 12 and 21. Therefore, each of the columnar portions 13 in the comparative example has a diameter that increases in the Z-direction, and each of the columnar portions 22 in the comparative example has a diameter that increases in the Z-direction.

The columnar portions 13 and 22 in the comparative example are respectively formed of the same memory insulators 33, channel semiconductor layers 34, and core insulators 35. A symbol P2 indicates a joint portion between the columnar portion 13 and the columnar portion 22. Each of the embedded insulators 23 in the comparative example contacts the columnar portions 22 in the stacked film 21, as illustrated in FIG. 4.

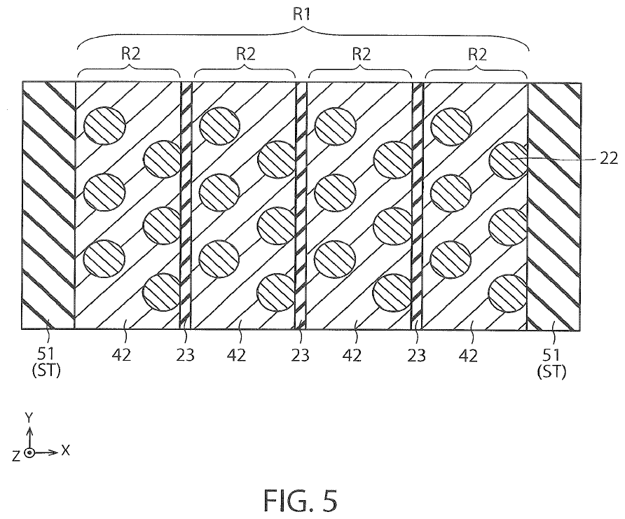

FIG. 5 is another cross-sectional view illustrating the structure of the semiconductor device in the comparative example of the first embodiment.

In the semiconductor device (FIG. 3) of the first embodiment, each of the embedded insulators 23 does not contact the columnar portions 22. On the other hand, in the semiconductor device (FIG. 5) in the comparative example, each of the embedded insulators 23 contacts the columnar portions 22.

Then referring to FIGS. 1 to 5, the semiconductor device of the present embodiment and the semiconductor device in the comparative example are compared with each other.

In the semiconductor device in the comparative example, each of the columnar portions 22 has a diameter that increases in the Z-direction. Therefore, a diameter in the vicinity of an upper end of the columnar portion 22 is larger than a diameter in the vicinity of a lower end of the columnar portion 22. On the other hand, in the semiconductor device of the present embodiment, each of the columnar portions 22 has the diameter that decreases in the Z-direction. Therefore, the diameter in the vicinity of the upper end of the columnar portion 22 is smaller than the diameter in the vicinity of the lower end of the columnar portion 22. As a result, the diameter of the columnar portion 22 illustrated in FIG. 5 (the comparative example) is large, while the diameter of the columnar portion 22 illustrated in FIG. 3 (the first embodiment) is small.

In both the present embodiment and the comparative example, each of the embedded insulators 23 is arranged in the vicinity of an upper face of the stacked film 21. Therefore, the embedded insulator 23 is arranged in the vicinity of the upper end of each of the columnar portions 22. In the comparative example, the diameter in the vicinity of the upper end of the columnar portions 22 is large, whereby the embedded insulator 23 is difficult to arrange not to contact the columnar portions 22. Accordingly, in the comparative example, there easily arises a problem that the embedded insulator 23 contacts the columnar portions 22. Alternatively, in the comparative example, a layout may be designed such that the embedded insulator 23 contacts the columnar portions 22, and the columnar portions 22 that contact the embedded insulator 23 may not be used for a memory cell. In the former case, a defect may occur in each of the columnar portions 22. In the latter case, waste may occur in each of the columnar portions 22.

On the other hand, in the present embodiment, the diameter in the vicinity of the upper end of each of the columnar portions 22 is small, whereby the embedded insulator 23 is easy to arrange not to contact the columnar portions 22. Therefore, the present embodiment makes it possible to easily prevent the embedded insulator 23 from contacting the columnar portions 22, thereby making it possible to avoid the above-described problem as in the comparative example. This makes it possible to increase respective densities of the columnar portions 22 in an XY plane when the plurality of columnar portions 22 are arranged in a two-dimensional array shape, thereby making it possible to increase an integration degree of the semiconductor device.

In the comparative example, there may easily occur respective defects in the columnar portions 13 and 22 due to the joint portion P2. On the other hand, the joint portion P1 in the present embodiment has a simpler structure than that of the joint portion P2 in the comparative example, which makes it possible to suppress the defects.

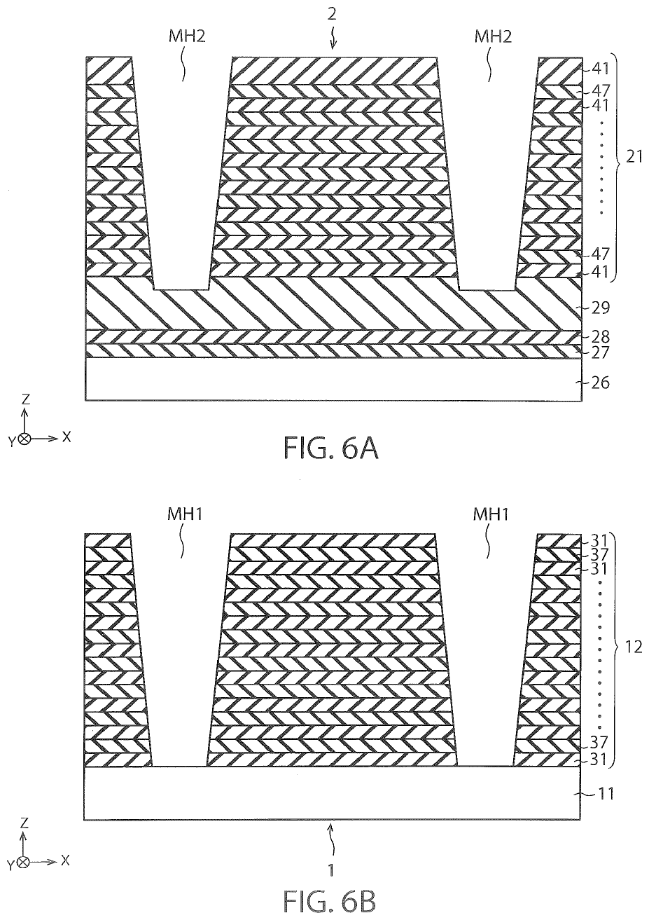

FIGS. 6A to 14 are cross-sectional views illustrating a method of manufacturing the semiconductor device of the first embodiment.

First, a substrate 11 is prepared, a stacked film 12 is formed on the substrate 11, and a plurality of memory holes MH1 are formed in the stacked film 12 (FIG. 6B). Similarly, a substrate 26 is prepared, an insulator 27, an insulator 28, and an insulator 29 are formed in this order on the substrate 26, a stacked film 21 is formed on the insulator 29, and a plurality of memory holes MH2 are formed in the stacked film 21 (FIG. 6A). The substrate 11 is an example of a first substrate, and the substrate 26 is an example of a second substrate. The substrate 26 is a semiconductor substrate such as a silicon substrate.

FIG. 6B illustrates a step of manufacturing a memory substrate 1. In FIG. 6B, a Z-direction is parallel to a surface of the substrate 11, and an X-direction and a Y-direction are perpendicular to the surface of the substrate 11. In FIG. 6B, the substrate 11 is upwardly arranged. The stacked film 12 is formed by alternately forming a plurality of insulators 31 and a plurality of sacrificial layers 37 on the substrate 11. Therefore, the sacrificial layers 37 are formed above the substrate 11 to be spaced from one another in the Z-direction. The sacrificial layers 37 are respectively used to form electrode layers 32. The sacrificial layers 37 are each an SiN film, for example. The sacrificial layers 37 are each an example of a first layer. Each of the memory holes MH1 is formed to extend in the Z-direction. The memory holes MH1 are formed in the stacked film 12 by lithography and reactive ion etching (RIE), for example. Therefore, each of the memory holes MH1 in the present embodiment has a diameter that increases in the Z-direction.

FIG. 6A illustrates a step of manufacturing a memory substrate 2. In FIG. 6A, the Z-direction is parallel to a surface of the substrate 26, and the X-direction and the Y-direction are perpendicular to the surface of the substrate 26. In FIG. 6A, the substrate 26 is upwardly arranged. The stacked film 21 is formed by alternately forming a plurality of insulators 41 and a plurality of sacrificial layers 47 on the substrate 26. Therefore, the sacrificial layers 47 are formed above the substrate 26 to be spaced from one another in the Z-direction. The sacrificial layers 47 are respectively used to form electrode layers 42. The sacrificial layers 47 are each an SiN film, for example. The sacrificial layers 47 are each an example of a second layer. Each of the memory holes MH2 is formed to extend in the Z-direction. The memory holes MH2 are formed in the stacked film 21 by lithography and RIE, for example. Therefore, each of the memory holes MH2 in the present embodiment has a diameter that increases in the Z-direction.

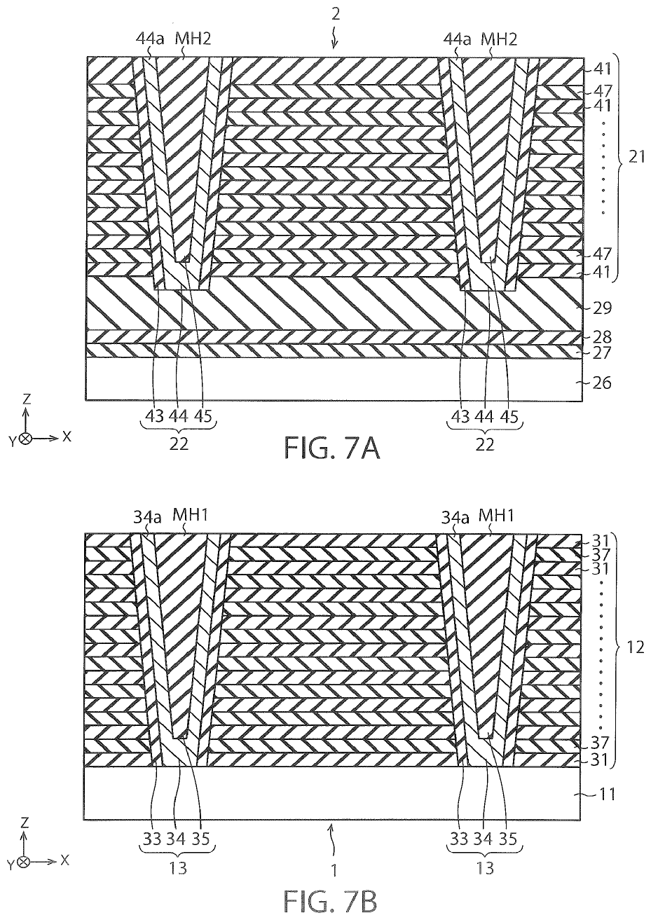

Then, a memory insulator 33, a semiconductor layer 34a, and a core insulator 35 are formed in this order in each of the memory holes MH1 (FIG. 7B). Similarly, a memory insulator 43, a semiconductor layer 44a, and a core insulator 45 are formed in this order in each of the memory holes MH2 (FIG. 7A). The memory insulator 33 is formed by forming a block insulator 33a, a charge storage layer 33b, and a tunnel insulator 33c in this order in each of the memory holes MH1 (see FIG. 2). The memory insulator 43 is formed by forming a block insulator 43a, a charge storage layer 43b, and a tunnel insulator 43c in this order in each of the memory holes MH2 (see FIG. 2).

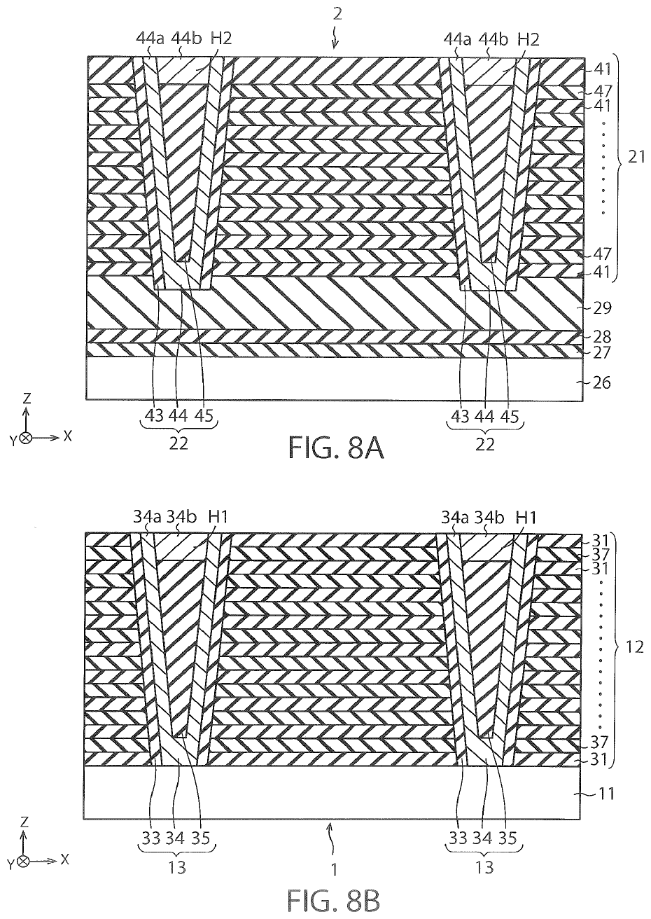

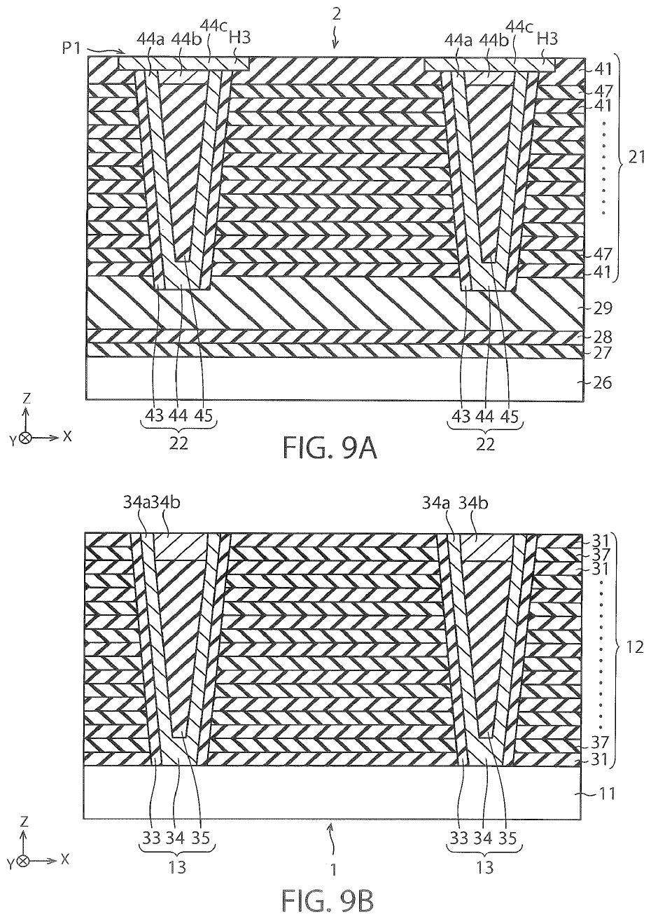

Then, by lithography and RIE, a hole H1 is formed in the core insulator 35 in each of the memory holes MH1, and a semiconductor layer 34b is formed in the hole H1 (FIG. 8B). Similarly, by lithography and RIE, a hole H2 is formed in the core insulator 45 in each of the memory holes MH2, and a semiconductor layer 44b is formed in the hole H2 (FIG. 8A). Then, by lithography and RIE, a hole H3 is formed in the semiconductor layer 44b, the semiconductor layer 44a, and the memory insulator 43 in each of the memory holes MH2, and a semiconductor layer 44c is formed in the hole H3 (FIG. 9A). In this manner, columnar portions 13 and 22 are respectively formed in the memory holes MH1 and MH2, as illustrated in FIGS. 9A and 9B. Each of the columnar portions 13 in the present embodiment is formed to have a diameter that increases in the Z-direction. Similarly, each of the columnar portions 22 in the present embodiment is formed to have a diameter that increases in the Z-direction.

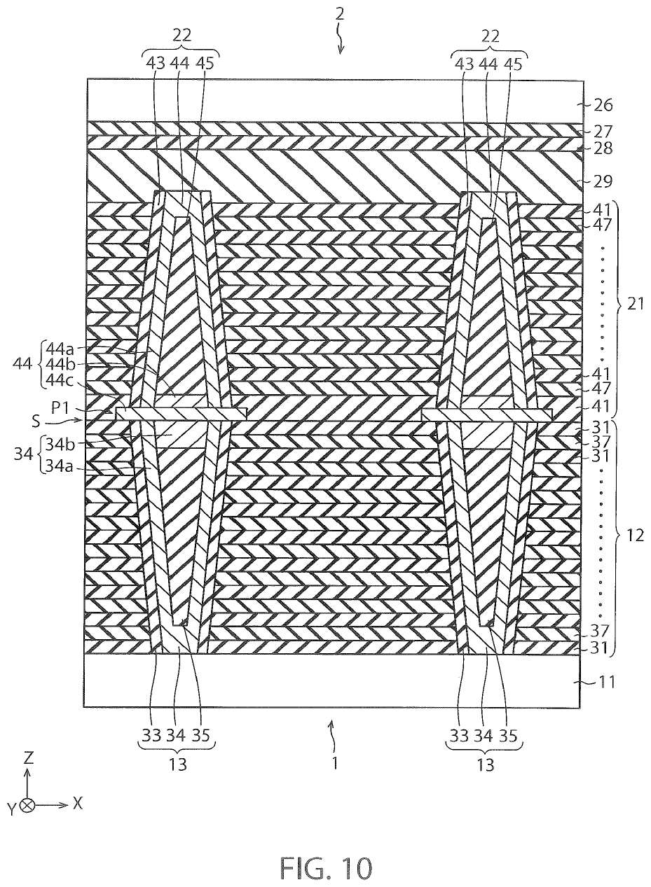

Then, the memory substrate 1 and the memory substrate 2 are bonded to each other (FIG. 10). That is, the substrate 11 and the substrate 26 are bonded to each other via the stacked films 12 and 21 and the columnar portions 13 and 22. As a result, the stacked film 21 is arranged on the stacked film 12, and the columnar portions 22 are respectively arranged on the columnar portions 13. In FIG. 10, the substrate 11 is upwardly arranged, and the substrate 26 is downwardly arranged. Accordingly, each of the columnar portions 13 illustrated in FIG. 10 has a diameter that increases in the Z-direction, and each of the columnar portions 22 illustrated in FIG. 10 has a diameter that decreases in the Z-direction.

In a step in FIG. 10, a lowermost insulator 41 in the stacked film 21 is bonded to an uppermost insulator 31 in the stacked film 12, and a channel semiconductor layer 44 in each of the columnar portion 22 is bonded to a channel semiconductor layer 34 in the corresponding columnar portion 13. In this case, the insulator 41 may be bonded to the insulator 31 using any method, and the channel semiconductor layer 44 may be bonded to the channel semiconductor layer 34 using any method. For example, the insulator 41 may be bonded to the insulator 31 with physical pressure. The channel semiconductor layer 44 may be bonded to the channel semiconductor layer 34 by dissolving a layer provided between the channel semiconductor layer 34 and the channel semiconductor layer 44.

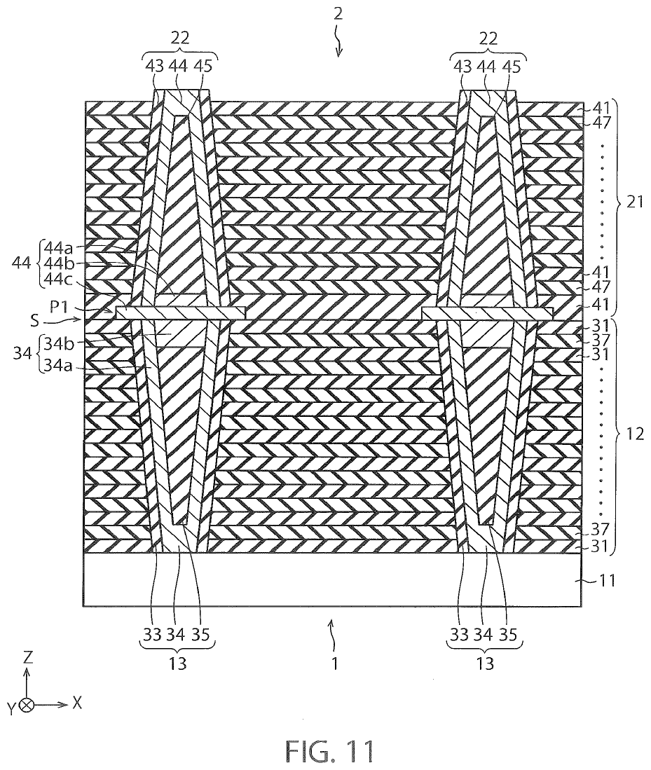

Then, the substrate 26, the insulator 27, the insulator 28, and the insulator 29 are removed (FIG. 11). As a result, a surface of the channel semiconductor layer 44 in each of the columnar portions 22 is exposed.

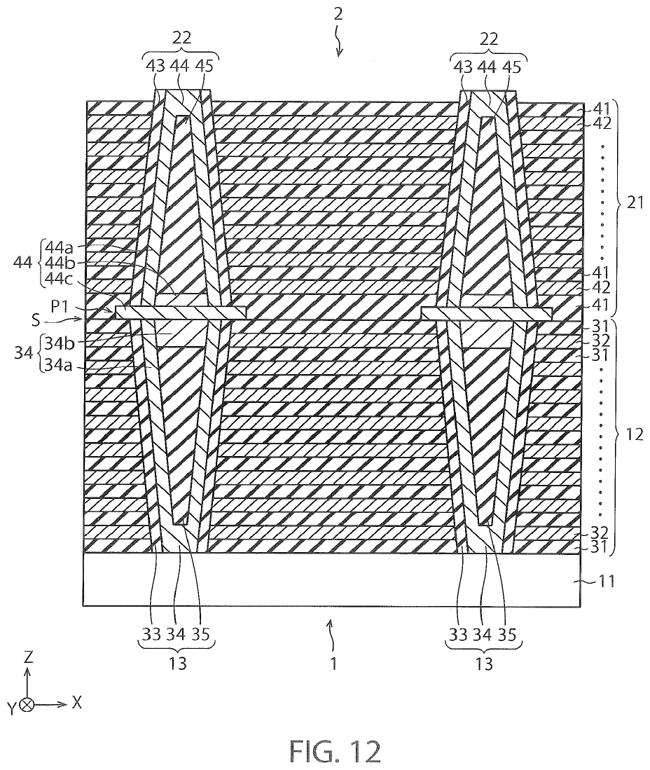

Then, a plurality of slits ST (see FIG. 3) are formed in the stacked films 21 and 12 by lithography and RIE, the sacrificial layers 37 and the sacrificial layers 47 are removed by wet etching from the slits ST, and a plurality of electrode layers 32 and a plurality of electrode layers 42 are respectively formed in spaces obtained by removing the sacrificial layers 37 and the sacrificial layers 47 (FIG. 12). As a result, the stacked film 12 changes to a structure including the plurality of insulators 31 and the plurality of electrode layers 32 alternately provided on the substrate 11. Similarly, the stacked film 21 changes to a structure including the plurality of insulators 41 and the plurality of electrode layers 42 alternately provided on the stacked film 12. In this manner, the sacrificial layers 37 are respectively replaced with the electrode layers 32, and the sacrificial layers 47 are respectively replaced with the electrode layers 42.

The plurality of slits ST are formed to extend in the Y-direction and the Z-direction and to be adjacent to one another in the X-direction. The slits ST are respectively filled with embedded insulators 51 after the sacrificial layers 37 and 47 are respectively replaced with the electrode layers 32 and 42 (see FIG. 3). Therefore, the embedded insulators 51 are formed to extend in the Y-direction and the Z-direction and to be adjacent to one another in the X-direction.

Each of the electrode layers 32 is formed by forming a block insulator 36 in the space and then forming a barrier metal layer 32a and an electrode material layer 32b in this order in the space, for example (see FIG. 2). Similarly, each of the electrode layers 42 is formed by forming a block insulator 46 in the space and then forming a barrier metal layer 42a and an electrode material layer 42b in the space, for example (see FIG. 2). The electrode layers 32 and 42 may be formed by forming a material common to the block insulators 36 and 46 in the above-described space and then forming a material common to the barrier metal layers 32a and 42a and a material common to the electrode material layers 32b and 42b in this order in the space. This causes the electrode layers 32 and 42 to be simultaneously formed.

The sacrificial layers 37 and 47 may be respectively replaced with the electrode layers 32 and 42 after at least a portion of each of the columnar portions 13 and 22 is formed before the memory substrate 1 and the memory substrate 2 are bonded to each other. For example, the replacement may be performed using the slits ST by forming a portion of each of the slits ST in the stacked film 12 and another part of each of the slit ST in the staked film 21 after the columnar portions 13 and are completed in the step illustrated in FIG. 9. The replacement may be performed using the slits ST by forming a portion of each of the slits ST in the stacked film 12 and another part of each of the slit ST in the staked film 21 after the memory insulators 33 and 43 are formed in the steps in FIGS. 7A and 7B.

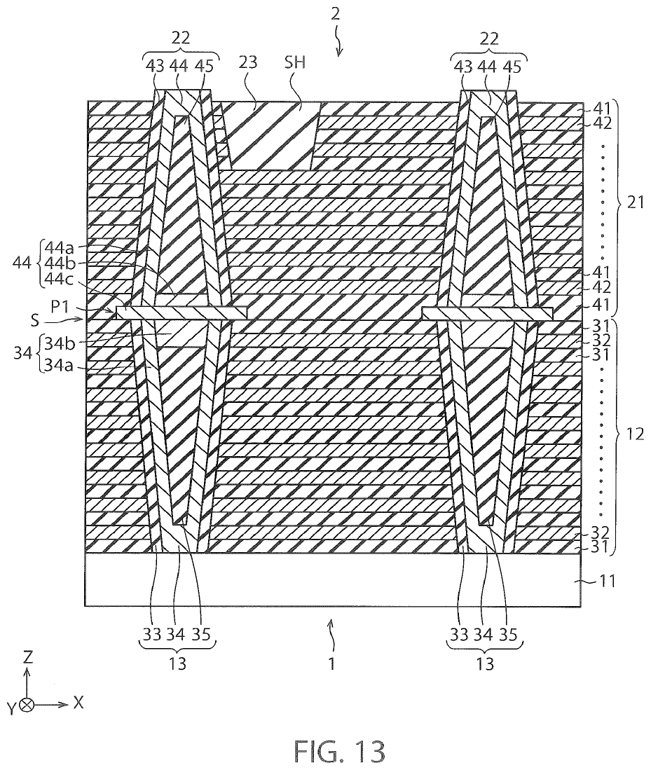

Then, a hole SH is formed in the stacked film 21 by lithography and RIE, and an embedded insulator 23 is formed in the hole SH (FIG. 13). In a step in FIG. 13, a plurality of holes SH are formed among the slits ST. FIG. 13 illustrates one of the holes SH. The holes SH are formed to extend in the Y-direction and the Z-direction and to be adjacent to one another in the X-direction. The plurality of embedded insulators 23 are respectively embedded in the holes SH. Therefore, the embedded insulators 23 are formed to extend in the Y-direction and the Z-direction and to be adjacent to one another in the X-direction (see FIG. 3). Each of the embedded insulators 23 in the present embodiment is formed to contact none of the columnar portions 22 in the stacked film 21. Each of the embedded insulators 23 in the present embodiment is formed in only the stacked film 21 out of the stacked films 12 and 21. The sacrificial layers 37 and 47 may be respectively replaced with the electrode layers 32 and 42 after the embedded insulators 23 are formed.

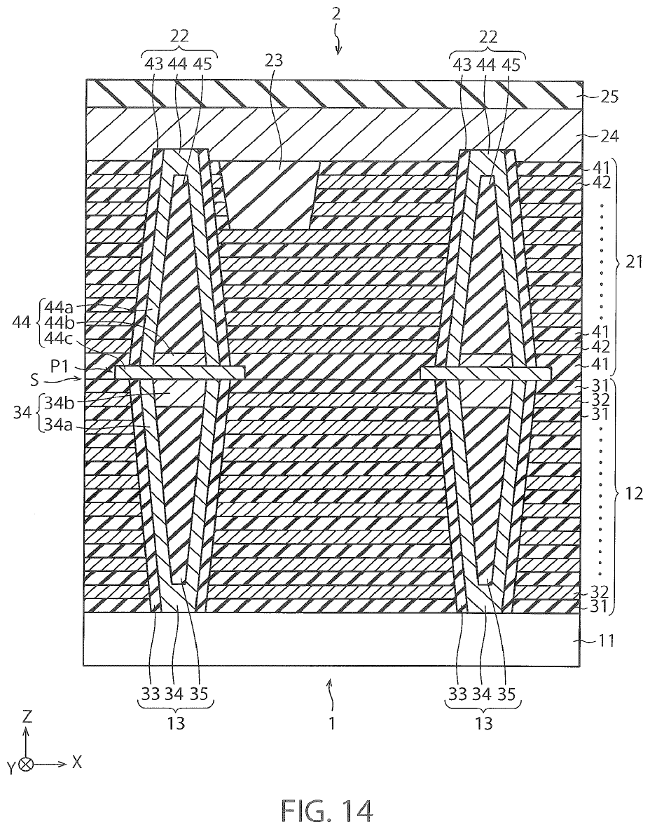

Then, an interconnection layer 24 is formed on the stacked film 21, the columnar portions 22, and the embedded insulators 23, and a passivation insulator 25 is formed on the interconnection layer 24 (FIG. 14). Then, various insulators, interconnection layers, plug layers, and the like are formed on the substrate 11. In this manner, the semiconductor device of the present embodiment is manufactured.

As described above, the semiconductor device of the present embodiment is manufactured by bonding the memory substrate 1 including the columnar portions 13 and the memory substrate 2 including the columnar portions 22 to each other. The semiconductor device of the present embodiment includes the columnar portions 13 provided on the substrate 11 and each having a diameter that increases in the Z-direction and the columnar portions 22 respectively provided on the columnar portions 13 and each having a diameter that decreases in the Z-direction. Therefore, the present embodiment makes it possible to prevent each of the embedded insulators 23 for dividing each of the electrode layers 42 from contacting the columnar portions 22.

When the memory substrate 1 and the memory substrate 2 are bonded to each other, the memory substrate 1 and the memory substrate 2 may be in a state of a wafer, or may be in a state of a chip obtained by dicing the wafer. The memory substrate 1 and the memory substrate 2 are manufactured by being bonded to each other in the state of the wafer. Therefore, after the memory substrate 1 and the memory substrate 2 in the present embodiment are bonded to each other, the memory substrate 1 and the memory substrate 2 are diced.

### Second Embodiment

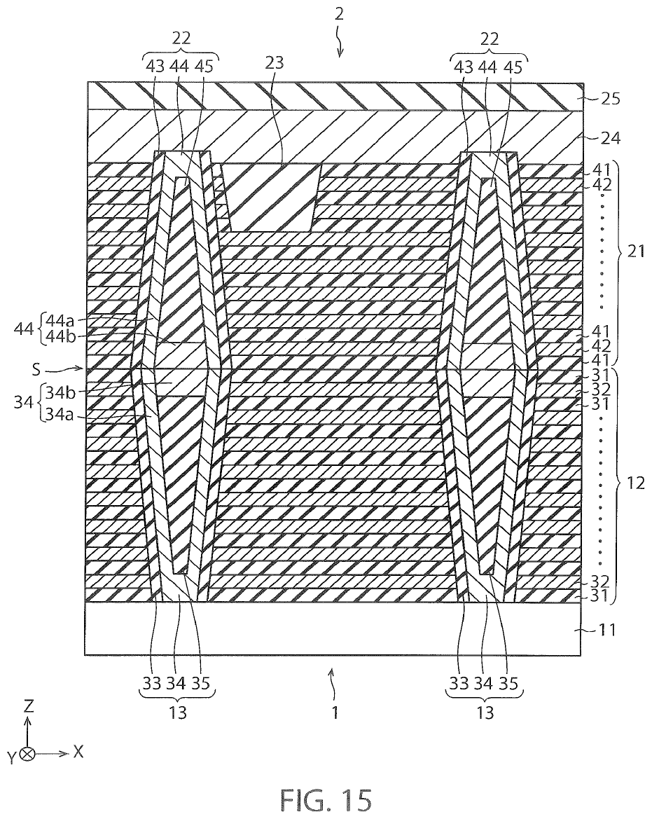

FIG. 15 is a cross-sectional view illustrating a structure of a semiconductor device of a second embodiment.

The semiconductor device of the present embodiment has a structure in which the semiconductor layer 44c is removed from the semiconductor device of the first embodiment. Therefore, upper faces of semiconductor layers 34a and 34b in each of columnar portions 13 respectively contact lower faces of semiconductor layers 44a and 44b in a corresponding columnar portion 22. In the present embodiment, an upper face of a channel semiconductor layer 34 and a lower face of a channel semiconductor layer 44 each have a solid shape.

The upper face of the semiconductor layer 34a in the present embodiment has a hollow shape, and the lower face of the semiconductor layer 44a in the present embodiment also has a hollow shape. Each of the columnar portions 13 includes the semiconductor layer 34b in the upper face of the semiconductor layer 34a, and each of the columnar portions 22 includes the semiconductor layer 44b in the lower face of the semiconductor layer 44a. The semiconductor layers 44a and 44b in the present embodiment are respectively directly formed on the semiconductor layers 34a and 34b.

The semiconductor device of the present embodiment can be manufactured by omitting the step illustrated in FIG. 9A in the method of manufacturing the semiconductor device of the first embodiment. Therefore, the semiconductor device of the present embodiment can be manufactured in a smaller number of steps than the semiconductor device of the first embodiment.

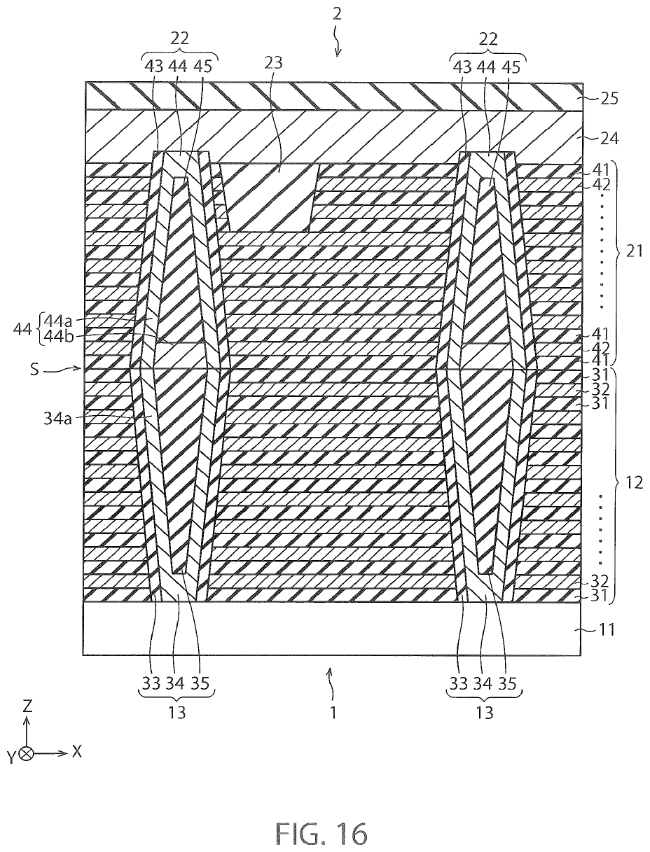

FIG. 16 is a cross-sectional view illustrating a structure of a semiconductor device of a first modification to the second embodiment.

The semiconductor device of the first modification has a structure in which the semiconductor layer 34b is removed from the semiconductor device of the second embodiment. Therefore, lower faces of semiconductor layers 44a and 44b in each of columnar portions 22 respectively contact upper faces of a channel semiconductor layer 34 (a semiconductor layer 34a) and a core insulator 35 in a corresponding columnar portion 13. In the modification, a lower face of a channel semiconductor layer 44 has a solid shape, and the upper face of the channel semiconductor layer 34 has a hollow shape.

The upper face of the semiconductor layer 34a in the modification has a hollow shape, and the lower face of the semiconductor layer 44a in the modification also has a hollow shape. Each of the columnar portions 13 includes the core insulator 35 in the upper face of the semiconductor layer 34a, and each of the columnar portions 22 includes the semiconductor layer 44b in the lower face of the semiconductor layer 44a. The semiconductor layer 44a in the modification is directly formed on the semiconductor layer 34a.

The semiconductor device of the modification can be manufactured by omitting the steps illustrated in FIGS. 9A and 8B in the method of manufacturing the semiconductor device of the first embodiment. Therefore, the semiconductor device of the modification can be manufactured in a smaller number of steps than the semiconductor device of the second embodiment.

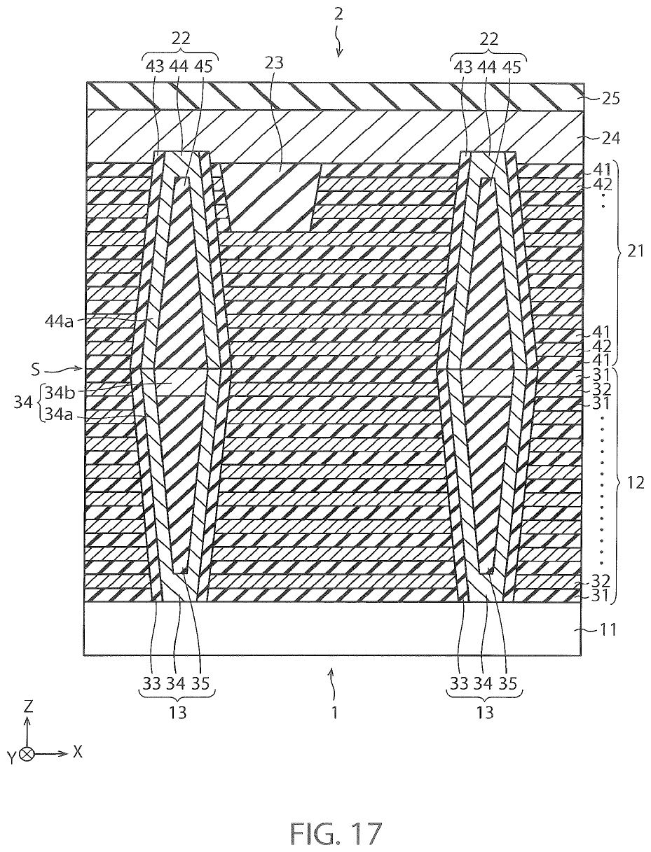

FIG. 17 is a cross-sectional view illustrating a structure of a semiconductor device of a second modification to the second embodiment.

The semiconductor device of the modification has a structure in which the semiconductor layer 44b is removed from the semiconductor device of the second embodiment. Therefore, upper faces of semiconductor layers 34a and 34b in each of columnar portions 13 respectively contact upper faces of a channel semiconductor layer 44 (a semiconductor layer 44a) and a core insulator 45 in a corresponding columnar portion 22. In the modification, an upper face of a channel semiconductor layer 34 has a solid shape, and a lower face of the channel semiconductor layer 44 has a hollow shape.

The upper face of the semiconductor layer 34a in the modification has a hollow shape, and the lower face of the semiconductor layer 44a in the modification also has a hollow shape. Each of the columnar portions 13 includes the semiconductor layer 34b in the upper face of the semiconductor layer 34a, and each of the columnar portions 22 includes a core insulator 45 in the lower face of the semiconductor layer 44a. The semiconductor layer 44a in the modification is directly formed on the semiconductor layer 34a.

The semiconductor device of the modification can be manufactured by omitting the steps illustrated in FIGS. 9A and 8A in the method of manufacturing the semiconductor device of the first embodiment. Therefore, the semiconductor device of the modification can be manufactured in a smaller number of steps than the semiconductor device of the second embodiment.

### Third Embodiment

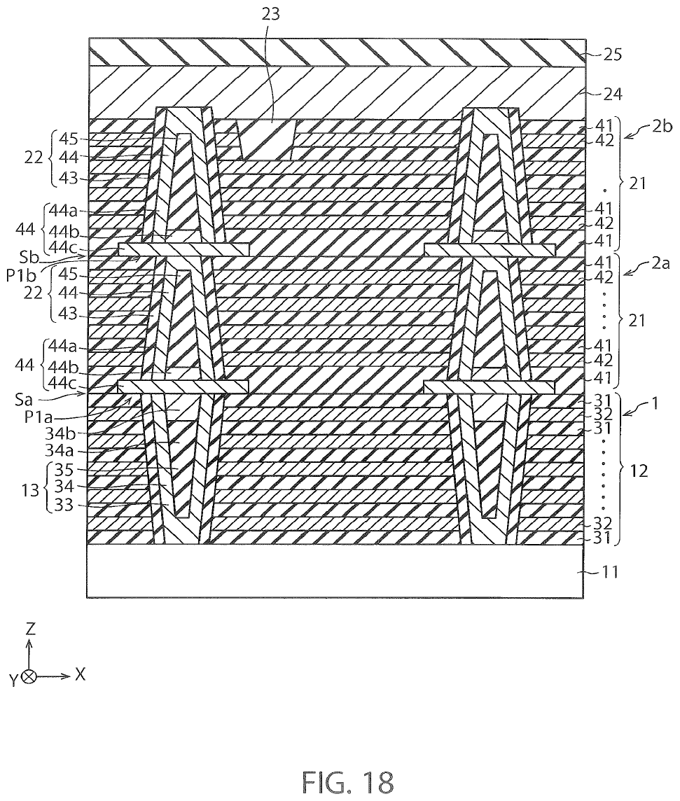

FIG. 18 is a cross-sectional view illustrating a structure of a semiconductor device of a third embodiment.

The semiconductor device of the present embodiment is manufactured by bonding a memory substrate 1 and a memory substrate 2a to each other and bonding the memory substrate 2a and a memory substrate 2b to each other. FIG. 18 illustrates a bonding face Sa between the memory substrate 1 and the memory substrate 2a and a bonding face Sb between the memory substrate 2a and the memory substrate 2b.

The memory substrate 1 in the present embodiment (FIG. 18) has the same structure as that of the memory substrate 1 in the first embodiment (FIG. 1). The memory substrate 2a in the present embodiment has a structure in which the embedded insulator 23, the interconnection layer 24, and the passivation insulator 25 are removed from the memory substrate 2 in the first embodiment. The memory substrate 2b in the present embodiment has the same structure as that of the memory substrate 2 in the first embodiment. The present embodiment makes it possible to more increase an integration degree of the semiconductor device than the first embodiment. A symbol P1a indicates a joint portion in the memory substrate 2a, and a symbol P1b indicates a joint portion in the memory substrate 2b.

A structure of electrode layers 42 and columnar portions 22 in each of memory substrates 2a and 2b in the present embodiment is similar to the structure of the electrode layers 42 and the columnar portions 22 in the memory substrate 2 illustrated in FIG. 2. The electrode layer 42, the columnar portion 22, a charge storage layer in a memory insulator 43, and a semiconductor layer 44a in the memory substrate 2b are respectively examples of a third electrode layer, a third columnar portion, a third charge storage layer, and a third semiconductor layer.

Therefore, each of the columnar portions 22 in each of the memory substrates 2a and 2b in the present embodiment has a shape close to a circular columnar shape, and a planar shape of each of the columnar portions 22 is a circular shape. Note that a side face of the columnar portion 22 in the present embodiment is inclined with respect to a Z-direction, and a diameter in the vicinity of an upper end of the columnar portion 22 is smaller than a diameter in the vicinity of a lower end of the columnar portion 22. Therefore, each of the columnar portions 22 in the present embodiment has a diameter that decrease in the Z-direction. That is, a diameter of each of the columnar portions 22 at a height decreases as the height increases. In FIG. 18, a width in an X-direction of each of the columnar portions 22 at a height decreases as the height increases.

From another viewpoint, when two portions respectively having different heights in each of the columnar portions 22 are paid attention to, a width in the X-direction of the higher portion is smaller than a width in the X-direction of the lower portion. The lower portion and the width thereof are respectively examples of a third or fifth portion and a third or fifth width. The higher portion and the width thereof are examples of a fourth or sixth portion and a fourth or sixth width.

The semiconductor device of the present embodiment can be manufactured by changing the method of manufacturing the semiconductor device of the first embodiment in the following manner.

First, memory substrates 1, 2a, and 2b in the present embodiment are manufactured in a similar manner to the memory substrates 1, 2, and 2 in the steps illustrated in FIGS. 6A to 9B. Then, the memory substrate 1 and the memory substrate 2a in the present embodiment are bonded to each other in a similar manner to the memory substrate 1 and the memory substrate 2 in the step illustrated in FIG. 10, and a substrate 26 or the like in the memory substrate 2a in the present embodiment is removed in a similar manner to the substrate 26 or the like in the memory substrate 2 in the step illustrated in FIG. 11. Then, the memory substrate 2a and the memory substrate 2b in the present embodiment are bonded to each other in a similar manner to the memory substrate 1 and the memory substrate 2 in the step illustrated in FIG. 10, and the substrate 26 or the like in the memory substrate 2b in the present embodiment is removed in a similar manner to the substrate 26 or the like in the memory substrate 2 in the step illustrated in FIG. 11. Note that when the memory substrate 2a and the memory substrate 2b are bonded to each other, both the memory substrate 2a and the memory substrate 2b are directed downward.

Then, sacrificial layers 37 and 47 in the memory substrates 1, 2a, and 2b in the present embodiment are respectively replaced with electrode layers 32 and 42 in a similar manner to the sacrificial layers 37 and 47 in the memory substrates 1 and 2 in the step illustrated in FIG. 12. In this case, a slit ST is formed to penetrate through stacked films 12 and 21 in the memory substrates 1, 2a, and 2b, and an embedded insulator 51 is embedded in the slit ST.

Then, the memory substrate 2b in the present embodiment is processed in a similar manner to the memory substrate 2 illustrated in FIGS. 13 and 14. In this case, a hole SH is formed in only the memory substrate 2b among the memory substrates 1, 2a, and 2b, and an embedded insulator 23 is embedded in the hole SH. In this manner, the semiconductor device of the present embodiment is manufactured.

The semiconductor device of the present embodiment may include a plurality of memory substrates 2a between the memory substrate 1 and the memory substrate 2b. In this case, the semiconductor device is manufactured by repeating the steps illustrated in FIGS. 10 and 11 the same number of times as the number of memory substrates 2a and 2b.

The memory substrates 1, 2a, and 2b in the present embodiment may have the same structure as that of the memory substrate 1 and 2 in the second embodiment or the modification thereto for columnar portions 13 and 22.

### Fourth Embodiment

FIG. 19 is a cross-sectional view illustrating a structure of a semiconductor device of a fourth embodiment.

The semiconductor device of the present embodiment includes an interconnection layer 52, a post portion 53, a post portion 54, an inter layer dielectric 55, an inter layer dielectric 56, a plurality of contact plugs 57, a contact plug 58, and a stepped region R in addition to components in the semiconductor device of the second embodiment. The semiconductor device of the present embodiment further includes a connection semiconductor layer 38 in a columnar portion 13. In FIG. 19, illustration of an interconnection layer 24 and a passivation insulator 25 is omitted.

An embedded insulator 51 and the interconnection layer 52 are formed in stacked films 12 and 21. Specifically, the embedded insulator 51 and the interconnection layer 52 are formed in this order in a slit ST (see FIG. 3) described above. The semiconductor device of the present embodiment includes a plurality of sets of embedded insulators 51 and interconnection layers 52 in the stacked films 12 and 21, and FIG. 19 illustrates one of the sets. The plurality of sets of embedded insulators 51 and interconnection layers 52 extend in a Y-direction and a Z-direction and are adjacent to each other in an X-direction.

The post portion 53 is formed in the stacked film 12 on a substrate 11, and the post portion 54 is formed on the post portion 53 in the stacked film 21. The post portions 53 and 54 are each an SiO₂ film, for example. The post portions 53 and 54 each have a columnar shape extending in the Z-direction. The post portion 53 in the present embodiment has a diameter that increases in the Z-direction, and the post portion 54 in the present embodiment has a diameter that decreases in the Z-direction.

The stepped region R is formed in a portion of the stacked film 21. In the stepped region R, insulators 41 and electrode layers 42 are processed in a stepped shape. The inter layer dielectric 55 is formed on the stepped region R in the stacked film 21 and on the post portion 54 in the stacked film 21. The inter layer dielectric 56 is formed on the stacked film 21, a columnar portion 22, an embedded insulator 23, the embedded insulator 51, the interconnection layer 52, and the inter layer dielectric 55.

The contact plugs 57 are formed in the inter layer dielectrics 55 and 56 and on the stepped region R in the stacked film 21. Each of the contact plugs 57 is formed on an upper face of the corresponding electrode layer 42, and is electrically connected to the corresponding electrode layer 42. The contact plug 58 is formed in the inter layer dielectric 56 and the memory insulator 43 and on a channel semiconductor layer 44, and is electrically connected to the channel semiconductor layer 44.

In the columnar portion 13 in the present embodiment, the connection semiconductor layer 38 is formed in the stacked film 12 on the substrate 11. The connection semiconductor layer 38 is an Si layer formed by epitaxial growth from a substrate 11, for example. A memory insulator 33, a channel semiconductor layer 34, and a core insulator 35 are formed on the connection semiconductor layer 38. The memory insulator 33 is formed on respective side faces of insulators 31 and electrode layers 32 in the stacked film 12. A semiconductor layer 34a in the channel semiconductor layer 34 is formed on a side face of the memory insulator 33 and an upper face of the connection semiconductor layer 38, and contacts the connection semiconductor layer 38. The core insulator 35 is formed on a side face and an upper face of the semiconductor layer 34a. A semiconductor layer 34b in the channel semiconductor layer 34 is formed on the side face of semiconductor layer 34a and an upper face of the core insulator 35, and contacts the semiconductor layer 34a.

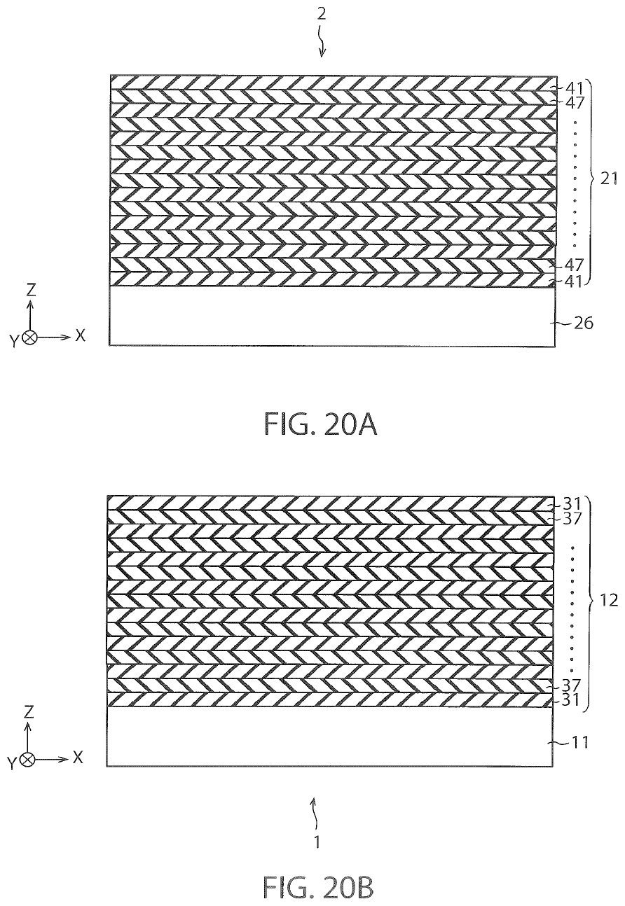

FIGS. 20A to 25 are cross-sectional views illustrating a method of manufacturing the semiconductor device of the fourth embodiment.

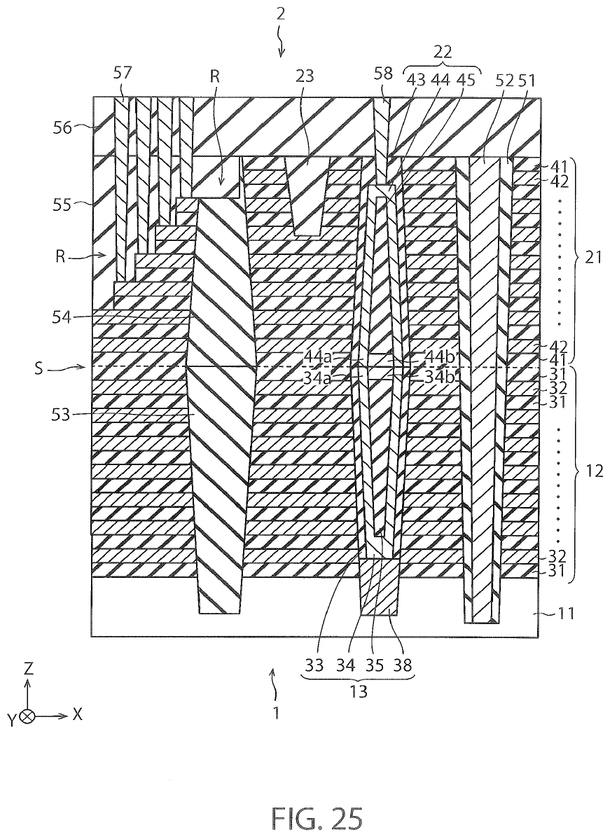

For the method illustrated in FIGS. 20A and 25, description is appropriately omitted for points common to those in the method illustrated in FIGS. 6A to 14, and points different from those in the method illustrated in FIGS. 6A to 14 will be mainly described.

First, a substrate 11 is prepared, and a stacked film 12 is formed on the substrate 11 (FIG. 20B). Similarly, a substrate 26 is prepared, and a stacked film 21 is formed on the substrate 26 (FIG. 20A). The stacked film 12 is formed by alternately forming a plurality of insulators 31 and a plurality of sacrificial layers 37 on the substrate 11. The stacked film 21 is formed by alternately forming a plurality of insulators 41 and a plurality of sacrificial layers 47 on the substrate 26.

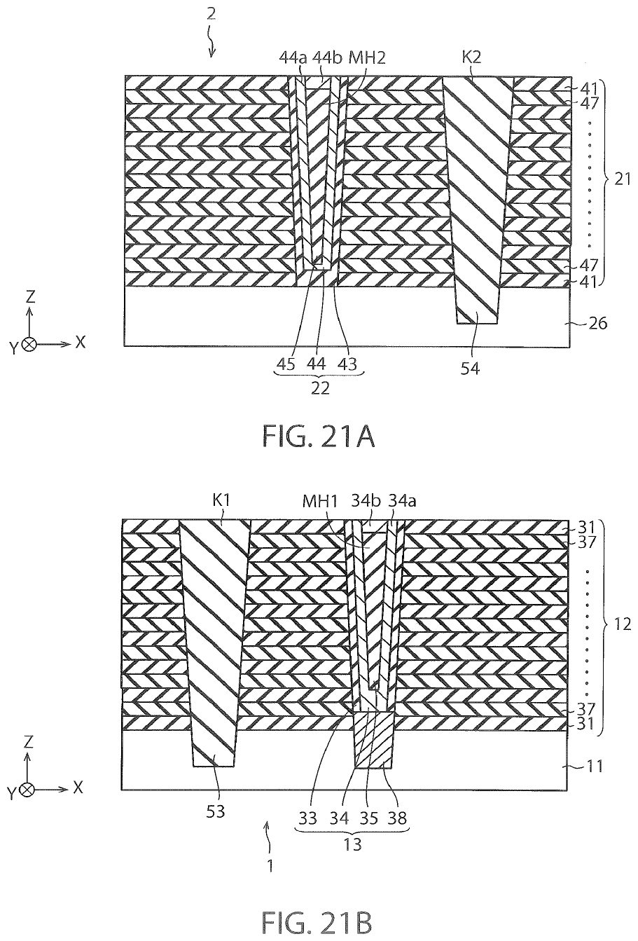

Then, a hole K1 is formed in the stacked film 12 by lithography and RIE, a post portion 53 is formed in the hole K1, a memory hole MH1 is formed in the stacked film 12 by lithography and RIE, and a columnar portion 13 is formed in the memory hole MH1 (FIG. 21B). Similarly, a hole K2 is formed in the stacked film 21 by lithography and RIE, a post portion 54 is formed in the hole K2, a memory hole MH2 is formed in the stacked film 21 by lithography and RIE, and a columnar portion 22 is formed in the memory hole MH2 (FIG. 21B). The columnar portion 13 is formed by forming a connection semiconductor layer 38 in the memory hole MH1 by epitaxial growth and then forming a memory insulator 33, a semiconductor layer 34a, a core insulator 35, and a semiconductor layer 34b in this order in the memory hole MH1.

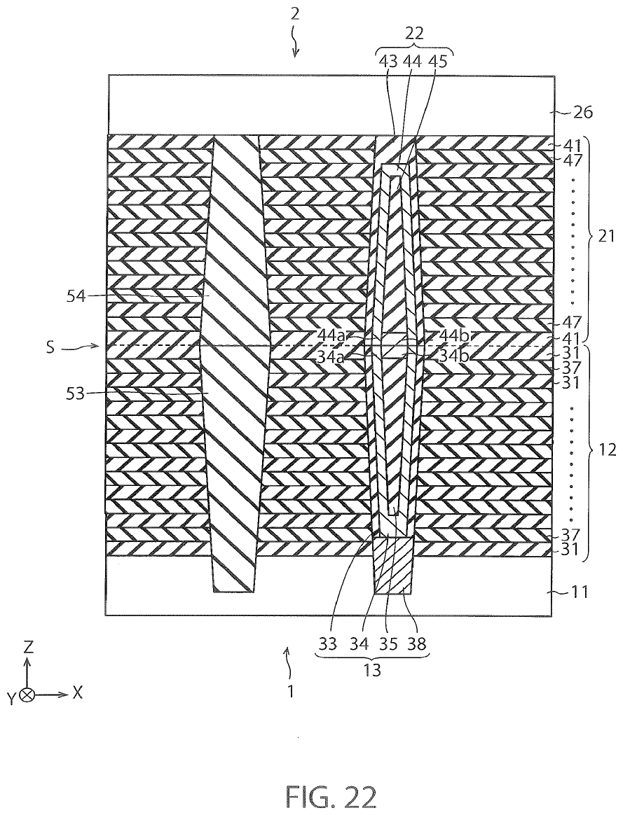

Then, a memory substrate 1 and a memory substrate 2 are bonded to each other (FIG. 22). That is, the substrate 11 and the substrate 26 are bonded to each other via the stacked films 12 and 21 and the columnar portions 13 and 22. As a result, the stacked film 21 is arranged on the stacked film 12, and the columnar portion 22 is arranged on the columnar portion 13. In FIG. 22, the substrate 11 is upwardly arranged, and the substrate 26 is downwardly arranged. Accordingly, the columnar portion 13 illustrated in FIG. 22 has a diameter that increases in the Z-direction, and the columnar portion 22 illustrated in FIG. 22 has a diameter that decreases in the Z-direction.

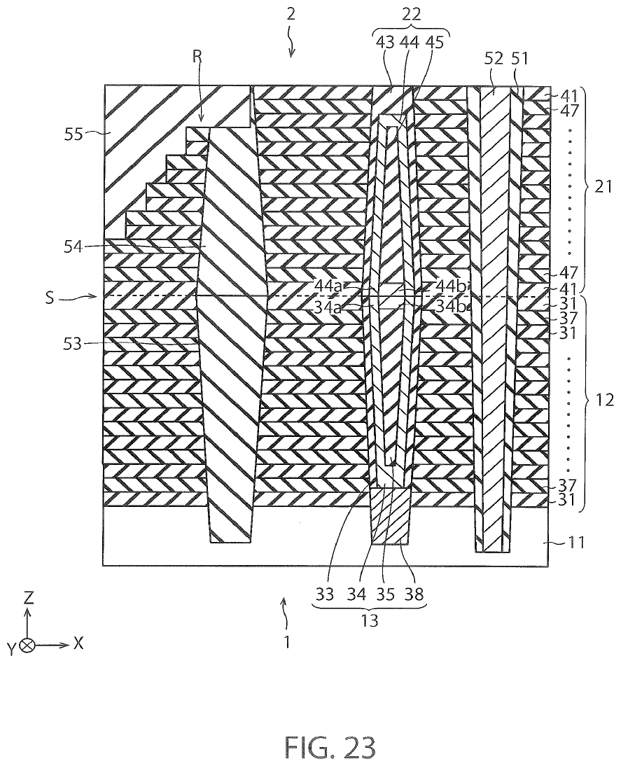

Then, the substrate 26 is removed (FIG. 23). As a result, respective surfaces of the post portion 54 and the columnar portion 22 are exposed. Then, a portion of the stacked film 21 is processed into a stepped shape by lithography and RIE (FIG. 23). As a result, a stepped region R is formed in the part of the stacked film 21. Then, an inter layer dielectric 55 is formed on the stepped region R (FIG. 23). As a result, the inter layer dielectric 55 is formed on the post portion 54.

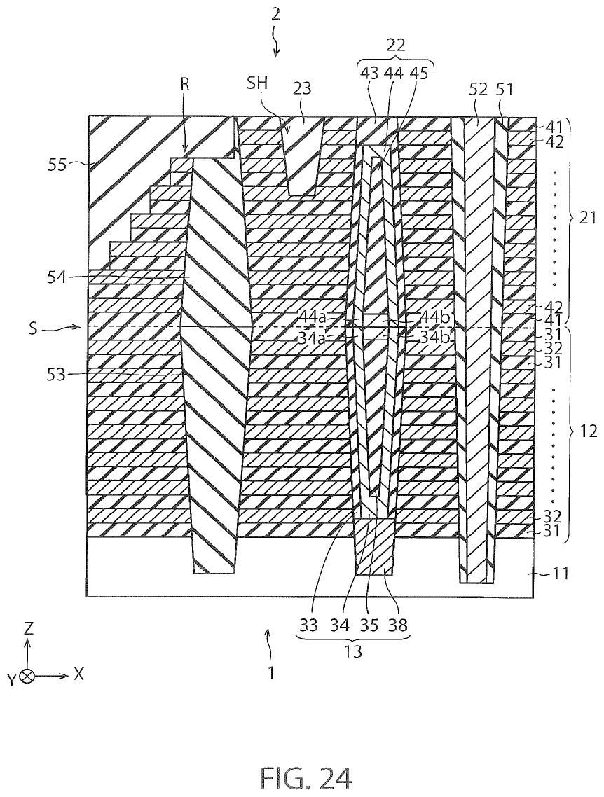

Then, a slit ST is formed in the stacked films 21 and 12 by lithography and RIE, sacrificial layers 37 and 47 are removed by wet etching from the slit ST, and electrode layers 32 and 42 are respectively formed in spaces obtained by removing the sacrificial layers 37 and 47 (FIG. 24). Then, an embedded insulator 51 and an interconnection layer 52 are formed in this order in the slit ST, a hole SH is formed in the stacked film 21 by lithography and RIE, and an embedded insulator 23 is formed in the hole SH (FIG. 24).

Then, an inter layer dielectric 56 is formed on the stacked film 21, the columnar portion 22, the embedded insulator 23, the embedded insulator 51, the interconnection layer 52, and the inter layer dielectric 55 (FIG. 25). Then, a plurality of contact plugs 57 are formed in the inter layer dielectrics 55 and 56 and on the stepped region R in the stacked film 21 (FIG. 25). Each of the contact plugs 57 is formed on an upper face of the corresponding electrode layer 42, and is electrically connected to the corresponding electrode layer 42. Then, a contact plug 58 is formed in the inter layer dielectric 56 and a memory insulator 43 and on a channel semiconductor layer 44 (FIG. 25). The contact plug 58 is formed to contact an upper face of the channel semiconductor layer 44, and is electrically connected to the channel semiconductor layer 44.

As described above, the semiconductor device of the present embodiment is manufactured by bonding the memory substrate 1 including the columnar portion 13 and the memory substrate 2 including the columnar portion 22 to each other. The semiconductor device of the present embodiment includes the columnar portion 13 provided on the substrate 11 and having a diameter that increases in the Z-direction and the columnar portion 22 provided on the columnar portion 13 and having a diameter that decreases in the Z-direction. Therefore, the present embodiment makes it possible to prevent the embedded insulator 23 for dividing each of the electrode layers 42 from contacting the columnar portion 22, like the first to third embodiments.

The memory substrates 1 and 2 in the present embodiment may respectively have the same structures as those of the memory substrates 1 and 2 in the first embodiment and the same structure as those of the memory substrates 1 and 2 in the modification to the second embodiment for the columnar portions 13 and 22.

In the first to fourth embodiments, the semiconductor device in each of the embodiments may be a three-dimensional semiconductor memory of a type different from that of the above-described three-dimensional semiconductor memory. For example, charge storage layers 33b and 43b may be each a layer of a floating gate type instead of a layer of a charge trap type. The charge storage layers 33b and 43b may be provided outside the columnar portions 13 and 22 instead of being provided in the columnar portions 13 and 22. A shape in an XY cross portion of each of the columnar portions 13 and 22 may be a shape (e.g., an elliptic shape or a square shape) other than a circle.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a plurality of first electrode layers spaced from one another in a first direction;
a plurality of second electrode layers provided above the first electrode layers, and spaced from one another in the first direction;
a first columnar portion extending in the first direction in the plurality of first electrode layers, and including a first semiconductor layer;
a second columnar portion provided on the first columnar portion, extending in the first direction in the plurality of second electrode layers, and including a second semiconductor layer;
a first charge storage layer provided between the plurality of first electrode layers and the first semiconductor layer; and
a second charge storage layer provided between the plurality of second electrode layers and the second semiconductor layer,
wherein
the second semiconductor layer is directly provided on the first semiconductor layer, or is provided on the first semiconductor layer via another semiconductor layer,
the first columnar portion includes a first portion having a first width in a second direction intersecting the first direction, and a second portion provided above the first portion and having a second width larger than the first width in the second direction, and
the second columnar portion includes a third portion having a third width in the second direction, and a fourth portion provided above the third portion and having a fourth width larger than the third width in the second direction.

2. The device of claim 1, wherein
the plurality of first electrode layers are provided above a substrate, and
the first direction is perpendicular to a surface of the substrate.

3. The device of claim 1, further comprising:
a first insulator provided in the first and second electrode layers,
a second insulator provided in the first and second electrode layers, and
a third insulator provided in only the second electrode layers out of the first and second electrode layers, positioned between the first and second insulators, and contacting none of second columnar portions in the second electrode layers.

4. The device of claim 3, wherein
the first and second insulators extend in a third direction intersecting the first direction and the second direction, and are adjacent to each other in the second direction, and
the third insulator extends in the third direction between the first and second insulators.

5. The device of claim 3, comprises, as the third insulator, a plurality of third insulators positioned between the first and second insulators.

6. The device of claim 5, wherein
the first and second insulators extend in a third direction intersecting the first direction and the second direction, and are adjacent to each other in the second direction, and
the plurality of third insulators extend in the third direction between the first and second insulators, and are adjacent to one another in the second direction.

7. The device of claim 3, wherein
a region between the first and second insulators corresponds to one finger of a memory, and
the third insulator divides the one finger into a plurality of pages.

8. The device of claim 1, wherein the second semiconductor layer is electrically connected to the first semiconductor layer.

9. The device of claim 1, wherein the second semiconductor layer is provided on the first semiconductor layer via the another semiconductor layer having a width larger than a width of an upper face of the first columnar portion in the second direction.

10. The device of claim 1, wherein
a shape of an upper face of the first semiconductor layer and a shape of a lower face of the second semiconductor layer are each a hollow shape, and
the first columnar portion includes a semiconductor layer in the upper face of the first semiconductor layer, and the second columnar portion includes a semiconductor layer in the lower face of the second semiconductor layer.

11. The device of claim 1, wherein
a shape of an upper face of the first semiconductor layer and a shape of a lower face of the second semiconductor layer are each a hollow shape, and
the first columnar portion includes an insulator in the upper face of the first semiconductor layer, or the second columnar portion includes an insulator in the lower face of the second semiconductor layer.

12. The device of claim 1, further comprising:
a plurality of third electrode layers provided above the second electrode layers, and spaced from one another in the first direction,
a third columnar portion provided on the second columnar portion, extending in the first direction in the plurality of third electrode layers, and including a third semiconductor layer, and
a third charge storage layer provided between the plurality of third electrode layers and the third semiconductor layer,
wherein
the third semiconductor layer is directly provided on the second semiconductor layer, or is provided on the second semiconductor layer via another semiconductor layer, and
the third columnar portion includes a fifth portion having a fifth width in the second direction, and a sixth portion provided above the fifth portion and having a sixth width larger than the fifth width in the second direction.

13. The device of claim 12, further comprising:
a first insulator provided in the first, second and third electrode layers,
a second insulator provided in the first, second and third electrode layers, and
a third insulator provided in only the third electrode layers among the first, second and third electrode layers, positioned between the first and second insulators, and contacting none of third columnar portions in the third electrode layers.

14. The device of claim 13, comprising, as the third insulator, a plurality of third insulators positioned between the first and second insulators.

15. The device of claim 12, wherein
the second semiconductor layer is electrically connected to the first semiconductor layer, and
the third semiconductor layer is electrically connected to the second semiconductor layer.

16. A method of manufacturing a semiconductor device, comprising:
forming a plurality of first layers spaced from one another in a first direction above a first substrate;
forming a first columnar portion extending in the first direction in the plurality of first layers and including a first semiconductor layer;
forming a plurality of second layers spaced from one another in a fourth direction above a second substrate;
forming a second columnar portion extending in the fourth direction in the plurality of second layers and including a second semiconductor layer; and
bonding the first substrate and the second substrate to each other via the first columnar portion and the second columnar portion such that the second columnar portion is arranged on the first columnar portion,
wherein
the first semiconductor layer is formed via a first charge storage layer in the plurality of first layers,
the second semiconductor layer is formed via a second charge storage layer in the plurality of second layers, and
the second semiconductor layer is directly arranged on the first semiconductor layer, or is arranged on the first semiconductor layer via another semiconductor layer.

17. The method of claim 16, further comprising replacing the first and second layers with first and second electrode layers, respectively, after forming at least portions of the first and second columnar portions.

18. The method of claim 17, wherein the first and second layers are replaced with the first and second electrode layers, respectively, after the first substrate and the second substrate are bonded to each other.

19. The method of claim 17, further comprising:
forming a first insulator in the first and second electrode layers or in the first and second layers, forming a second insulator in the first and second electrode layers or in the first and second layers, and forming a third insulator in only the second electrode layers out of the first and second electrode layers or in only the second layers out of the first and second layers,
wherein the third insulator is positioned between the first and second insulators, and formed to contact none of second columnar portions in the second electrode layers or the second layers.

20. The method of claim 17, wherein
the first columnar portion is formed to include a first portion having a first width in a second direction intersecting the first direction, and a second portion provided above the first portion and having a second width larger than the first width in the second direction, and
the second columnar portion is formed to include a third portion having a third width in the second direction, and a fourth portion provided above the third portion and having a fourth width larger than the third width in the second direction.
